(19) United States
(12) Patent Application Publication
(10) Pub. No.: US 2015/0303365 A1
(43) Pub. Date: Oct. 22, 2015

(54) THERMOELECTRIC CONVERSION MODULE

(71) Applicants: HITACHI CHEMICAL COMPANY, LTD., Tokyo (JP); HONDA MOTOR CO., LTD., Tokyo (JP)

(72) Inventors: Masanao Tominaga, Matsudo-shi (JP); Takahiro Jinushi, Matsudo-shi (JP); Zenzo Ishijima, Matsudo-shi (JP); Masayoshi Mori, Wako-shi (JP); Takeshi Yamagami, Wako-shi (JP); Hiroshi Matsuda, Wako-shi (JP); Shiyouhei Yamashita, Wako-shi (JP)

(21) Appl. No.: 14/435,553

(22) PCT Filed: Oct. 25, 2013
(86) PCT No.: PCT/JP2013/006335

§ 371 Date: Apr. 14, 2015

(30) Foreign Application Priority Data
Oct. 26, 2012 (JP) 2012-236208
Apr. 18, 2013 (JP) 2013-087813

(51) Int. Cl. H01L 35/32; H01L 35/10; H01L 35/30

(52) U.S. Cl. CPC H01L 35/32; H01L 35/30; H01L 35/10

(57) ABSTRACT

A thermoelectric conversion module includes: a piping for flowing a compressible fluid; high temperature electrodes which are provided on a top surface and a bottom surface of the piping and electrically insulated from the piping; thermoelectric conversion elements which are provided on the respective high temperature electrodes, each element containing at least a pair of p-type thermoelectric semiconductor and n-type thermoelectric semiconductor which are electrically connected in series with one another; low temperature electrodes which are provided on the respective thermoelectric conversion elements and electrically connect the p-type thermoelectric semiconductor in series with the n-type thermoelectric semiconductor; and a first case member for accommodating the piping, the high temperature electrodes, the thermoelectric conversion elements and the low temperature electrodes so as to form a space for flowing a refrigerant for the low temperature electrodes.

### TECHNICAL FIELD

The present invention relates to a thermoelectric conversion module which uses as heat source waste heat from compressible fluid such as exhaust gas from, e.g., various industrial equipments and automobiles.

### BACKGROUND OF THE RELATED ART

A conventional thermoelectric conversion module is normally configured such that electrodes are provided on the top surface and the bottom surface of a plurality of p-type thermoelectric semiconductors and a plurality of n-type thermoelectric semiconductors, that is, on the surface in the side of high temperature heat source and on the surface in the side of low temperature heat source so as to constitute the corresponding electric circuit and electric insulating plates are provided on the outer surfaces of the electrodes.

On the other hand, such an attempt as using waste heat of compressible fluid such as exhaust gas from various industrial equipments and automobiles is made (refer to Patent document No. 1)

In order to receive the heat from the compressible fluid effectively, it is preferable the wall of the piping where the compressible fluid is flowed, that is, the piping wall of the exhaust piping is thinner. However, if the piping wall of the exhaust piping is thinner, the piping wall is deformed so that the piping wall cannot be thinner. In this point of view, the heat receiving from the compressible fluid is deteriorated so that the power generation efficiency results in being reduced. Moreover, since thermal distribution is generated in the exhaust piping, the thermoelectric module is not uniformly expanded so as to be in danger of destruction thereof.

On the other hand, in order to enhance the power generation efficiency of the thermoelectric module, it is considered that the temperature of the low temperature heat source of the thermoelectric conversion element is more decreased. In this case, a large amount of refrigerant is flowed in the refrigerant chamber which is formed in the thermoelectric conversion module and to which the low temperature heat source of the thermoelectric conversion element is exposed. However, refrigerant kept at extremely low temperature is high in cost so that the total cost of the thermoelectric module is disadvantageously raised. In the use of a refrigerant commercially available, since the refrigerant is flowed through the refrigerant chamber, it is difficult to decrease the temperature of the low temperature heat source of the thermoelectric conversion element.

Patent document No. 1: Japanese Patent Application Laid-open 2007-221895 (JP-A 2007-221895)

### SUMMARY OF THE INVENTION

### Problem to be Solved by the Invention

It is an object of the present invention to provide a thermoelectric conversion module which uses as heat source waste heat from compressible fluid such as exhaust gas from various industrial equipments and automobiles and enhance thermoelectric conversion efficiency thereof and which is very practical.

### Means for Solving the Problem

In order to solve out the aforementioned problem, the present invention relates to a thermoelectric conversion module, including:

a piping for flowing a compressible fluid;

high temperature electrodes which are provided on a top surface and a bottom surface of the piping and electrically insulated from the piping;

thermoelectric conversion elements which are provided on the respective high temperature electrodes, each element containing at least a pair of p-type thermoelectric semiconductor and n-type thermoelectric semiconductor which are electrically connected in series with one another;

low temperature electrodes which are provided on the respective thermoelectric conversion elements and electrically connect the p-type thermoelectric semiconductor in series with the n-type thermoelectric semiconductor; and

a first case member for accommodating the piping, the high temperature electrodes, the thermoelectric conversion elements and the low temperature electrodes so as to form a space for flowing a refrigerant for the low temperature electrodes,

wherein the compressible fluid or the refrigerant is flowed to areas where the thermoelectric conversion elements are provided at an inner side or an outer side of the piping.

According to the present invention, since the compressible fluid is flowed only in the inner side of the piping on which the thermoelectric conversion element is provided, the waste heat can be effectively conducted to the thermoelectric conversion element so as to enhance the efficiency of utilization of the waste heat. As a result, the Seebeck effect of the thermoelectric conversion element is enhanced so that the efficiency of thermoelectric conversion of the thermoelectric conversion element is also enhanced so that a large amount of electric energy can be taken out of the thermoelectric conversion module.

Moreover, since the refrigerant is flowed only in the outer side of the piping on which the thermoelectric conversion element is provided, the cold heat can be effectively conducted to the thermoelectric conversion element from the refrigerant. Therefore, since the thermoelectric conversion element can be efficiently and effectively cooled, the Seebeck effect of the thermoelectric conversion element is enhanced and the efficiency of thermoelectric conversion is also enhanced so that a large amount of electric energy can be taken out of the thermoelectric conversion module.

Here, the constitution of the present invention is simple, but is based on the conception as the result of research and development over a number of years by the inventors. The conception has not been considered by any inventor.

In an aspect of the present invention, at least a portion of the inner space of the piping which is arranged almost orthogonal to the flowing path direction of the compressible fluid in the piping and is positioned at the non-formation area of the thermoelectric conversion element can be closed.

In this case, the at least a portion of the inner space of the piping of the thermoelectric conversion module, in which the compressible fluid such as exhaust gas of various industrial equipments and automobiles is flowed, for example, the inner space being positioned at the non-formation area of the thermoelectric conversion element, is closed. Therefore, the compressible fluid is flowed only in the inner space of the piping which is positioned at the formation area of the thermoelectric conversion element and is not flowed, e.g., in the edge spaces of the piping which is positioned at the non-formation area of the thermoelectric conversion area. Namely, the deterioration in the efficiency of thermoelectric conversion can be suppressed due to the flow of the compressible fluid in the inner space positioned at the non-formation area of the thermoelectric conversion element.

Therefore, since the waste heat from the compressible fluid can be conducted to the top surface and the bottom surface on which the thermoelectric conversion element is provided, in comparison to the conventional configuration where the compressible fluid is fluid entirely in the inner space of the piping, the efficiency of utilization of the waste heat can be enhanced. As a result, since the waste heat of the compressible fluid flowed in the piping can be effectively conducted to the lower side of the thermoelectric conversion element, the Seebeck effect of the thermoelectric conversion element is enhanced to increase the efficiency of thermoelectric conversion so that a large amount of electric energy can be taken out of the thermoelectric conversion module.

Namely, according to the present aspect, the efficiency of thermoelectric conversion of the thermoelectric conversion element can be enhanced and thus a large amount of electric energy can be taken out of the thermoelectric conversion module by the simple means of narrowing the flow path of the compressible fluid to be flowed in the piping.

The closing of the inner space of the piping can be carried out by providing a sealing member in the inner space of the piping, for example, or in the alternative, dent at least a side surface of the piping toward the inner space.

In another aspect of the present invention, the thermoelectric conversion module can be configured such that a second case member is provided at the outside of a first case member so as to form a refrigerant chamber for flowing a refrigerant for low temperature electrode and to accommodate the first case member and a flow path guiding plate is provided in the refrigerant chamber so as to be narrowed from the inlet of the refrigerant chamber to the formation area of the thermoelectric conversion element.

In this case, the flow path guiding plate is provided in the refrigerant chamber formed between the first case member and the second case member for accommodating the first case member so as to be narrowed from the inlet of the refrigerant chamber toward the formation area of the thermoelectric conversion element. Therefore, the refrigerant to be flowed in the refrigerant chamber is forcibly supplied to the formation area of the thermoelectric conversion element so as to cool the formation area efficiently and effectively.

Therefore, since the cold heat from the refrigerant can be effectively conducted to the side of the low temperature heat source of the thermoelectric conversion element, the efficiency of utilization of the refrigerant can be enhanced. As a result, the Seebeck effect of the thermoelectric conversion element can be enhanced so as to increase the efficiency of thermoelectric conversion so that a large amount of electric energy can be taken out of the thermoelectric conversion module. Namely, according to the present aspect, the efficiency of thermoelectric conversion of thermoelectric conversion element can be enhanced so that a large amount of electric energy can be taken out of the thermoelectric conversion module by the simple means of providing the flow path guiding plate formed so as to be narrowed from the inlet toward the formation area of the thermoelectric conversion element.

Here, the flow path guiding plate can be provided so as to form a gap for at least a portion of the top wall of the first case member or at least a portion of the bottom wall of the second case member.

If the non-formation area of the thermoelectric conversion element is excessively heated by the compressible fluid kept at high temperature flowing in the piping, for example, some voids are formed in the refrigerant due to the local heating by the compressible fluid and thus the flow of the refrigerant may be disturbed. As described above, however, if the flow path guiding plate is provided so as to form the gap for the at least a portion of the top wall of the first case member or the at least a portion of the bottom wall of the second case member, the non-formation area of the thermoelectric conversion element cannot be excessively heated and thus the aforementioned disadvantage can be resolved because the refrigerant is leaked slightly to the non-formation of the thermoelectric conversion element from the area defined by the flow path guiding member.

Moreover, the flow path guiding member may be bonded with at least a portion of the top wall of the first case member or in the alternative, at least a portion of the bottom wall of the second case member. In this case, since the flow path guiding member is fixed to the first case member or the second case member, the shift of the flow path guiding plate due to the refrigerant to be flowed in the space between the first case member and the second case member can be prevented so that the refrigerant can be stably supplied to the formation area of the thermoelectric conversion element. In addition, the flow path guiding member can be provided surely so as to form the gap for the at least a portion of the top wall of the first case member or at least a portion of the bottom wall of the second case member.

In still another aspect of the present invention, a heat exchange member may be provided in the refrigerant chamber. In this case, since the cold heat of the refrigerant to be flowed in the refrigerant chamber can be effectively conducted to the side of the low temperature heat source of the thermoelectric conversion element via the heat exchange member, the efficiency of utilization of the refrigerant can be much enhanced. As a result, the Seebeck effect of the thermoelectric conversion element is much enhanced so as to increase the efficiency of the thermoelectric conversion of the thermoelectric conversion element so that a large amount of electric energy can be taken out of the thermoelectric conversion module.

### Effect of the Invention

According to the present invention can be provided a thermoelectric conversion module which uses as heat source waste heat from compressible fluid such as exhaust gas from various industrial equipments and automobiles and enhance thermoelectric conversion efficiency thereof and which is very practical.

### BRIEF DESCRIPTION OF THE DRAWINGS

FIG. 1 is a perspective view schematically illustrating a thermoelectric conversion module according to a first embodiment.

FIG. 2 is a plan view of the thermoelectric conversion module illustrated in FIG. 1.

FIG. 3 is a cross sectional view of the thermoelectric conversion module illustrated in FIG. 1, taken on line I-I.

FIG. 4 is a cross sectional view of the thermoelectric conversion module illustrated in FIG. 1, taken on line II-II.

FIG. 5 is a perspective view schematically illustrating the piping of the thermoelectric conversion module illustrated in FIG. 1.

FIG. 6 is a plan view schematically illustrating a thermoelectric conversion module according to a second embodiment.

FIG. 7 is a cross sectional view of the thermoelectric conversion module illustrated in FIG. 6.

FIG. 8 is a perspective view of the piping of the thermoelectric conversion module illustrated in FIG. 6.

FIG. 9 is a perspective view of a thermoelectric conversion module according to a third embodiment.

FIG. 10 is a perspective view illustrating the state where an outer second case member is released from the thermoelectric conversion module illustrated in FIG. 9.

FIG. 11 is a perspective view illustrating the state where the outer second case member and a first case member for accommodating a thermoelectric conversion element which is positioned at the inner side of the second case member are released from the thermoelectric conversion module illustrated in FIG. 9.

FIG. 12 is a cross sectional view of the thermoelectric conversion module illustrated in FIG. 9, taken on line III-III.

FIG. 13 is a cross sectional view of the thermoelectric conversion module illustrated in FIG. 9, taken on line IV-IV.

FIG. 14 is a cross sectional view schematically illustrating a thermoelectric conversion module according to a fourth embodiment.

FIG. 15 is a perspective view schematically illustrating a thermoelectric conversion module according to a fifth embodiment.

FIG. 16 is a perspective view illustrating the state where the outer second case member is released from the thermoelectric conversion module illustrated in FIG. 15.

### MODE FOR CARRYING OUT THE INVENTION

Hereinafter, the details and other features of the thermoelectric conversion module according to the present invention will be described referring to embodiments.

### First Embodiment

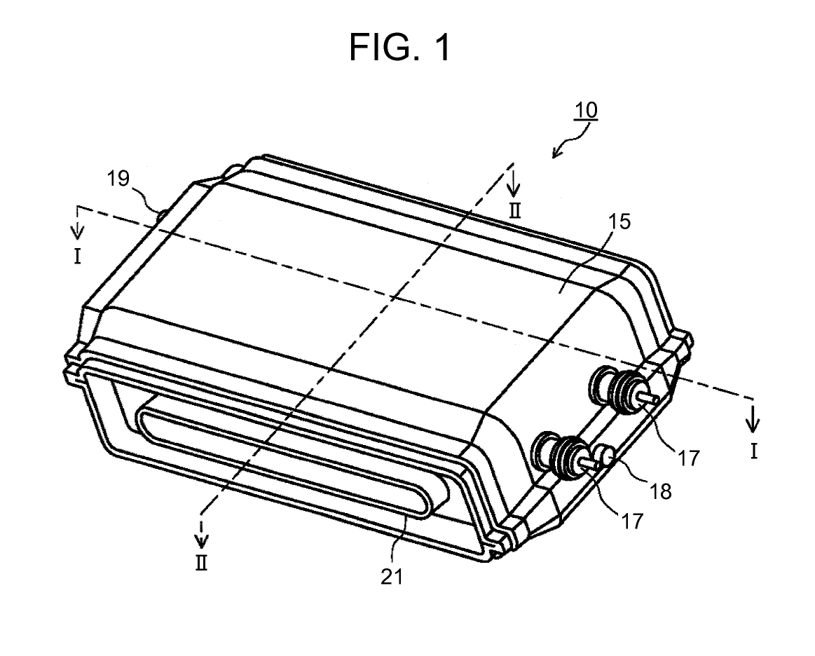

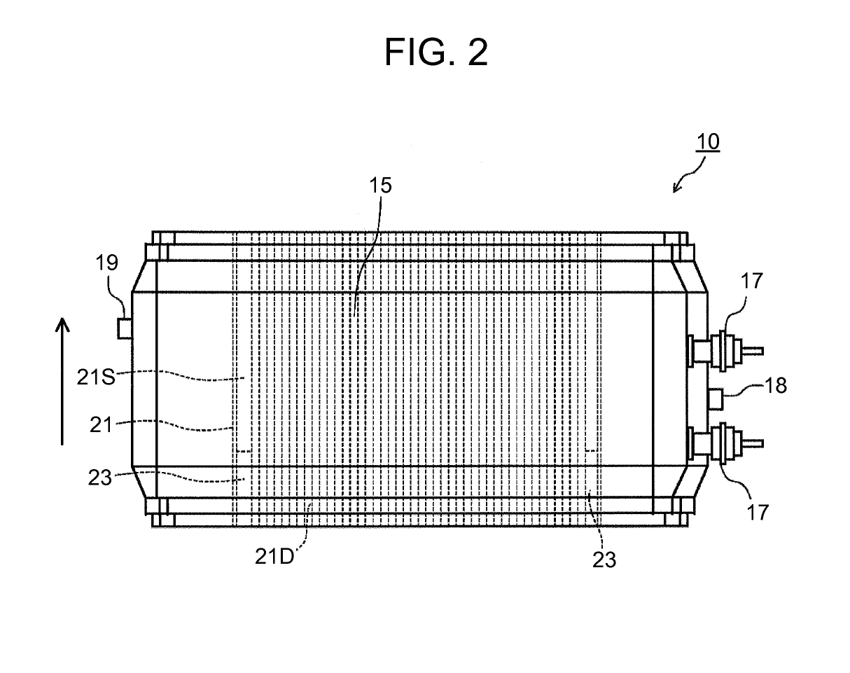

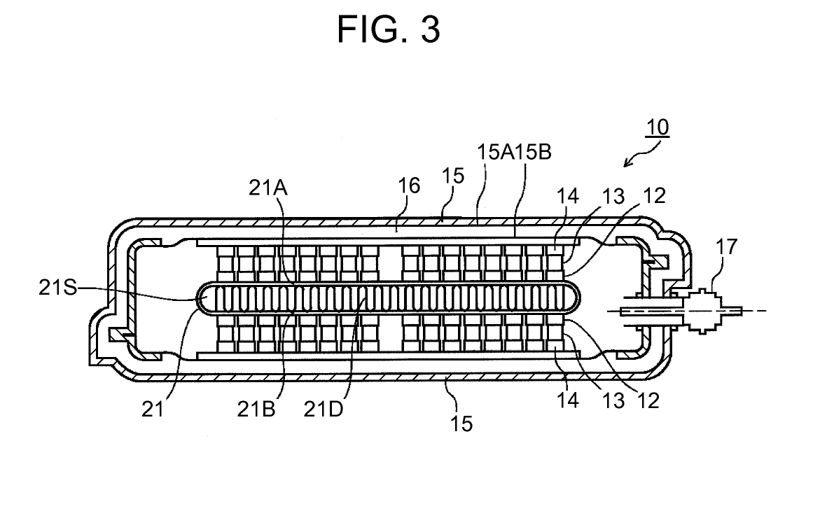

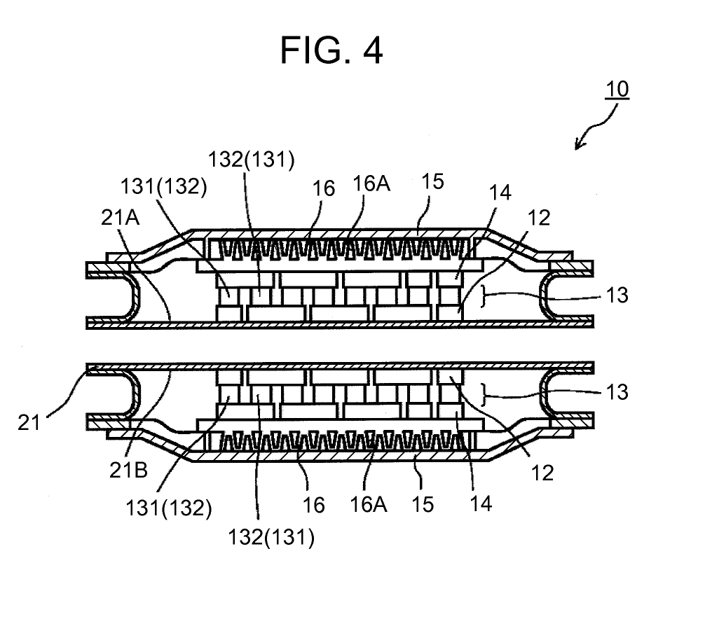

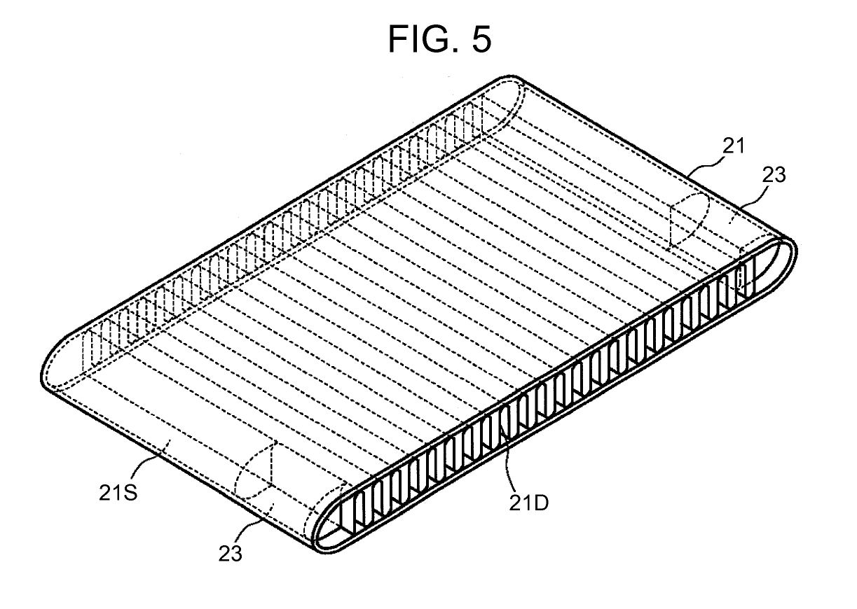

FIGS. 1 to 5 are views schematically illustrating a thermoelectric conversion module according to the present embodiment. FIG. 1 is a perspective view schematically illustrating the thermoelectric conversion module, and FIG. 2 is a plan view of the thermoelectric conversion module illustrated in FIG. 1. FIG. 3 is a cross sectional view of the thermoelectric conversion module illustrated in FIG. 1, taken on line I-I, and FIG. 4 is a cross sectional view of the thermoelectric conversion module illustrated in FIG. 1, taken on line II-II. FIG. 5 is a perspective view schematically illustrating the piping of the thermoelectric conversion module illustrated in FIG. 1.

As illustrated in FIGS. 1 to 5, the thermoelectric conversion module 10 includes a cylindrical piping 21 for flowing a compressible fluid which has a flat top surface 21A and bottom surface 21B and high temperature electrodes 12, 12 which are provided on the respective top surface 21A and the bottom surface 21B of the piping 21 and electrically insulated from the piping 21. Moreover, thermoelectric conversion elements 13, 13 are provided on the respective high temperature electrodes 12, 12, each thermoelectric conversion element 13 having p-type thermoelectric semiconductors 131 and n-type thermoelectric semiconductors 132 which are provided in the shape of matrix so as to be adjacent to one another and electrically connected in series with one another. Furthermore, low temperature electrodes 14, 14 are provided on the respective thermoelectric conversion elements 13, 13 so as to electrically connect the p-type thermoelectric semiconductors 131 in series with the n-type thermoelectric semiconductors 132 and to be contacted with the piping 21 in the state of electric insulation from the piping 21.

A fin 21D is provided in the inner space corresponding to the top formation area and the bottom formation area of the thermoelectric conversion elements 13, 13, and a sealing member 23 is provided in the inner space 21S positioned at the edge of the piping 21 in the front side of the introduction direction of a compressible fluid shown by an arrow in figures so as to seal the inner space 21S.

The sealing member 23 may be incorporated in the inner space 21S simultaneously when the inner space 21S is formed or in the alternative, by post-processing.

In this embodiment, the sealing member 23 is provided in the front side of the introduction direction of the compressible fluid, but the position of the sealing member is not limited only if the effect/function, which will be described hereinafter, can be exhibited. Alternatively, the sealing member 23 may be provided in the rear side or in the center side of the inner space along the introduction direction of the compressible fluid.

The sealing member 23 may be made of bulky material or plate-shaped, that is rid-shaped material. The thus obtained rid-shaped sealing member 23 may be provided in the front side or the rear side of the inner space 21S along the introduction direction of the compressible fluid. Alternatively, the rid-shaped sealing member 23 may be provided in the center of the inner space 21S along the introduction direction of the compressible fluid.

As illustrated in FIG. 3, a fin 21D is formed in the piping 21 so as to conduct the waste heat from the compressible fluid to be flowed in the piping 21 to the top surface 21A and the bottom surface 21B of the piping 21.

The piping 21, the high temperature electrodes 12, 12, the thermoelectric conversion elements 13, 13 and the low temperature electrodes 14, 14 are accommodated in an airtight case member 15, and a space 16 is defined and formed by the top wall 15A and the bottom wall 15B of the case member 15 so as to introduce and discharge a refrigerant therein through an inlet 18 and outlet 19 which are provided outside from the case member 15 (thermoelectric conversion module 10) and cool the low temperature electrodes 14, 14 (refer to FIG. 3).

As illustrated in FIG. 4, moreover, a cooling fin 16A is provided opposite to the inlet 18 and the outlet 19 of the refrigerant in the space 16 so as to conduct the cold heat from the refrigerant to the low temperature electrodes 14, 14 effectively.

The case member 15 is configured such that the portion where the high temperature electrodes 12, 12, the thermoelectric conversion element 13, 13 and the low temperature electrodes 14, 14 are accommodated and the space 16 is formed becomes thickest so that the portions except the thickest portion are stepwise thinned toward the outer side thereof.

The space accommodating the high temperature electrodes 12, 12, the thermoelectric conversion elements 13, 13 and the low temperature electrodes 14, 14 is evacuated and maintained in the state of vacuum.

Here, the high temperature electrodes 12, 12 are contacted with the top surface 21A and the bottom surface 21B of the piping 21 while the low temperature electrodes 14, 14 are contacted with the low wall 15B opposite to the top wall 15A, the top wall 15A and the low wall 15B forming the space for flowing the refrigerant. In this case, the high temperature electrodes 12, 12 or the low temperature electrodes 14, 14 may be bonded via brazing member.

Moreover, by setting the space accommodating the thermoelectric conversion elements 13, 13, etc., in the state of vacuum, the thermoelectric conversion elements 13, 13 are pressed by the low wall 15B of the case member 15 so as to enhance the adhesion of the aforementioned contact areas.

Here, at the aforementioned contact areas, a buffer material, a spare material or the like may be provided between the top surface 21A, the bottom surface 21B of the piping 21 and the high temperature electrodes 12, 12, and between the low wall 15B of the piping 21 and the low temperature electrodes 14, 14.

Furthermore, electrode terminals 17, 17 for taking the electric energy generated at the thermoelectric conversion elements 13, 13 out of the elements 13, 13 are electrically connected with the case member 15 (thermoelectric conversion module 10) via lead wires (not shown).

The piping 21 and the sealing member 23 are made of, e.g., stainless steel so as to resist corrosion gas contained in the compressible fluid such as exhaust gas from various industrial equipments and automobiles, etc.

High heat resistance, high mechanical strength and higher electric conductivity are required for the high temperature electrodes 12, 12 and the low temperature electrodes 14, 14. In this point of view, the high temperature electrodes 12, 12 and the low temperature electrodes 14, 14 are made of, e.g., Mo, Cu, W, Ti, Ni, an alloy thereof or stainless steel. The electrode terminals 17, 17 may be made of the same material as the electrodes 12, 12 and 14, 14.

It is preferable that the p-type thermoelectric semiconductors 131 and the n-type thermoelectric semiconductors 132 which form the thermoelectric conversion elements 13, 13 are made of a semiconductor material which has low heat conductivity and generates large difference of electric potential due to the Seebeck effect caused from large difference in temperature between the high temperature side and the low temperature side. As the semiconductor material may be exemplified Bi—Te based semiconductor material, Pb—Te based semiconductor material, Si—Ge based semiconductor material or Mg—Si based semiconductor material.

The case member 15 may be made of, e.g., Mg, Al, Mo, Cu, W, Ti, Ni, Fe, stainless steel or an alloy thereof in light of the weight reduction, corrosion-resistance and stiffness of various industrial equipments and automobiles on which the thermoelectric conversion modules 10 are mounted.

The lead wire (not shown and to be described hereinafter) may be made of electric conductive material such as Cu, Ag, Au, Ni, Fe or an alloy thereof.

In the thermoelectric conversion module 10 illustrated in FIGS. 1 to 4, the compressible fluid such as exhaust gas from various industrial equipments and automobiles is introduced into the piping 21 so that the top surface 21A and the bottom surface 21B of the piping 21 are heated by the waste heat from the compressible fluid. On the other hand, the refrigerant is introduced into the space 16 of the case member 15. The heat which is utilized for heating the top surface 21A and the bottom surface 21B of the piping 21 is conducted to the bottom sides of the thermoelectric conversion elements 13, 13 via the high temperature electrodes 12, 12, thereby heating the bottom sides of the elements 13, 13. On the other hand, the cold heat from the refrigerant introduced into the space 16 is conducted to the top sides of the thermoelectric conversion elements 13, 13 via the low temperature electrodes 14, 14, thereby cooling the top sides of the thermoelectric conversion elements 13, 13.

As a result, electromotive force is generated in the thermoelectric conversion elements 13, 13 due to the Seebeck effect so that the corresponding current is flowed through the thermoelectric conversion elements 13, 13 via the high temperature electrodes 12, 12 and the low temperature electrodes 14, 14 which electrically connect in series the p-type thermoelectric semiconductors 131 and the n-type thermoelectric semiconductors 132 which form the elements 13, 13, and taken out of the thermoelectric conversion module 10 via the electrode terminals 17, 17 and the lead wires (not shown).

In this case, since the Seebeck effect, that is, the efficiency of thermoelectric conversion is increased as the difference in temperature between the top sides and the bottom sides of the thermoelectric conversion elements 13, 13 is increased, as described above, it is required that the waste heat from the compressible fluid to be flowed in the piping 21 is utilized effectively as possible.

In the thermoelectric conversion module 10 according to this embodiment, the sealing member 23 is provided in the inner space 21S positioned at both ends of the inner space in which the fin 21D of the piping 21 is provided, namely, both edges of the piping 21 such that the compressible fluid is not flowed in the inner space 21S. Therefore, the compressible fluid is flowed in the inner space corresponding to the bottom area and the top area of the piping 21 on which the thermoelectric conversion elements 13, 13 are formed, namely the area in which the fin 21D is formed. In this manner, the loss in pressure of the compressible fluid, which results from the compressible fluid being flowed in the inner space 21S corresponding to the non-formation area of the thermoelectric conversion elements 13, 13, can be suppressed.

Therefore, since the waste heat from the compressible fluid can be conducted to the top surface 21A and the bottom surface 21B of the piping 21 on which the thermoelectric conversion elements 13, 13 are provided, in comparison to the conventional configuration where the compressible fluid is flowed entirely in the inner space of the piping 21, the efficiency of utilization of the waste heat can be enhanced. As a result, since the waste heat of the compressible fluid flowed in the piping 21 can be effectively conducted to the bottom sides of the thermoelectric conversion elements 13, 13, the Seebeck effect of the thermoelectric conversion element 13, 13 is enhanced to increase the efficiency of thermoelectric conversion so that a large amount of electric energy can be taken out of the thermoelectric conversion module 10.

Namely, according to this embodiment, the efficiency of thermoelectric conversion of the thermoelectric conversion elements 13, 13 can be enhanced and thus a large amount of electric energy can be taken out of the thermoelectric conversion module 10 by the simple means of narrowing the flow path of the compressible fluid to be flowed in the piping.

### Second Embodiment

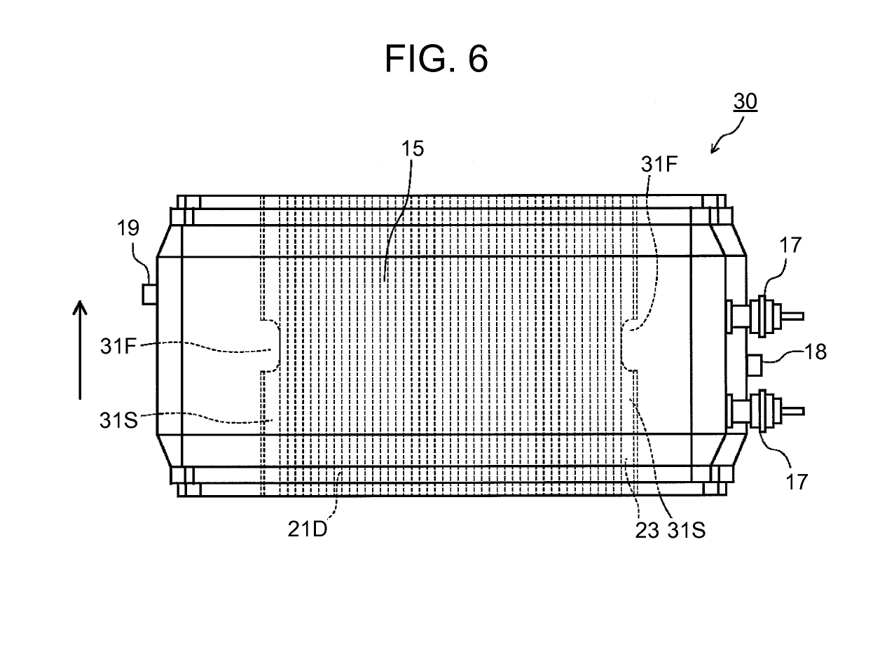

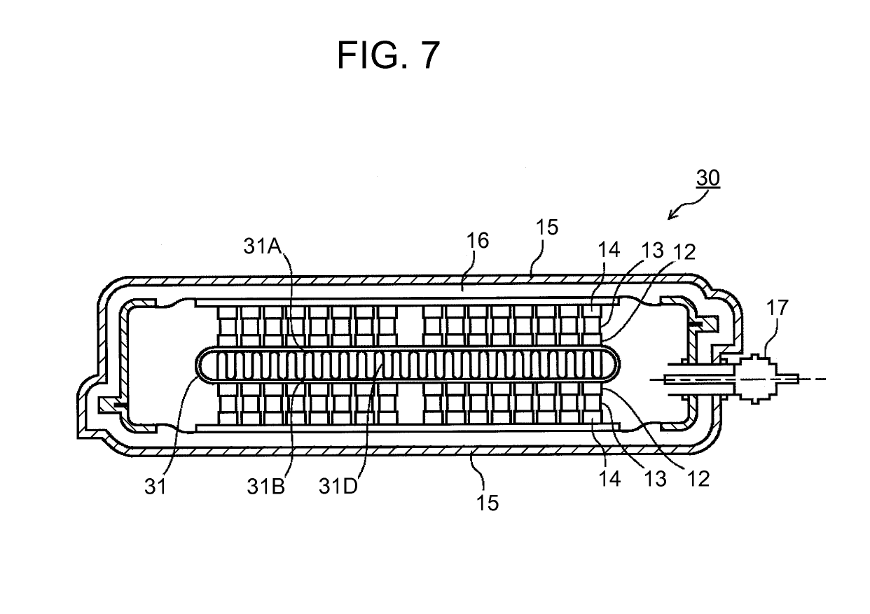

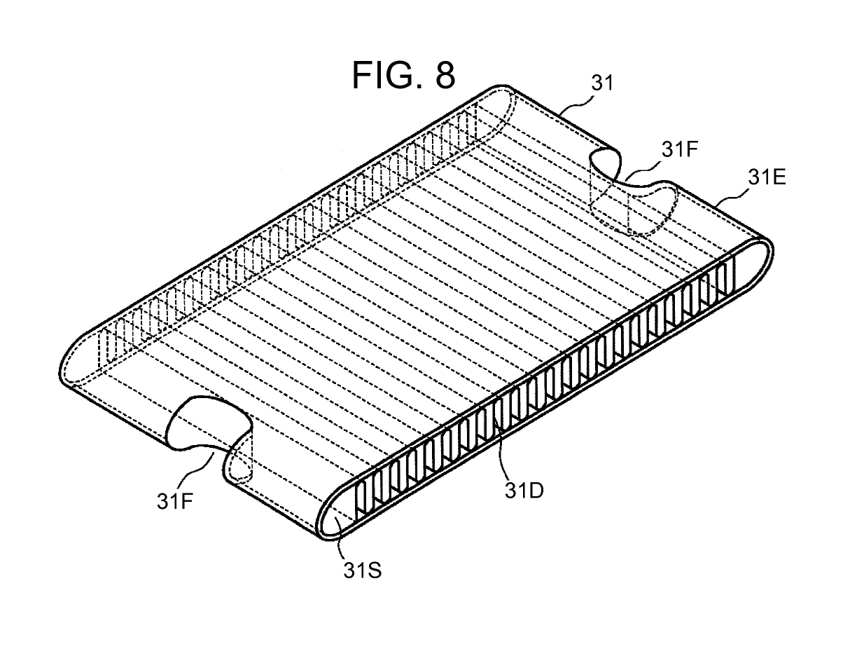

FIGS. 6 to 8 are views schematically illustrating a thermoelectric conversion module according to the present embodiment. FIG. 6 is a plan view schematically illustrating the thermoelectric conversion module and corresponds to the plan view relating to the thermoelectric conversion module 10 illustrated in FIG. 2. FIG. 7 is a cross sectional view illustrating the thermoelectric conversion module and corresponds to the cross sectional view relating to the thermoelectric conversion module 10 illustrated in FIG. 3. FIG. 8 is a perspective view schematically illustrating only the piping employed in the thermoelectric conversion module.

The total structure of the thermoelectric conversion module of the present embodiment is configured as the one illustrated in FIG. 1 relating to the first embodiment and thus omitted.

Like or corresponding components in the thermoelectric conversion module 10 illustrated in FIGS. 1 to 4 are designated by the same symbols.

In the thermoelectric conversion module 30 of the present embodiment, the portion of the side surface 31E of the piping 31 is processed and depressed toward the inner space 31S so as to contacted with the edge of the fin 31D, thereby closing the inner space 31S of the piping 31, instead of closing the inner space 21S of the piping 21 in the thermoelectric conversion module 10 relating to the first embodiment by providing the sealing member 23 in the inner space 21S.

In this embodiment, therefore, the compressible fluid introduced into the piping 31 is flowed only in the inner space in which the fin 31D is formed and which corresponds to the bottom area and the top area of the piping 31 on which the thermoelectric conversion elements 13, 13 are formed.

Therefore, since the waste heat from the compressible fluid can be conducted to the top surface 31A and the bottom surface 31B of the piping 31 on which the thermoelectric conversion elements 13, 13 are provided, in comparison to the conventional configuration where the compressible fluid is flowed entirely in the inner space of the piping 31, the efficiency of utilization of the waste heat can be enhanced. As a result, since the waste heat of the compressible fluid flowed in the piping 31 can be effectively conducted to the bottom sides of the thermoelectric conversion elements 13, 13, the Seebeck effect of the thermoelectric conversion element 13, 13 is enhanced to increase the efficiency of thermoelectric conversion so that a large amount of electric energy can be taken out of the thermoelectric conversion module 30.

Namely, according to this embodiment, the efficiency of thermoelectric conversion of the thermoelectric conversion elements 13, 13 can be enhanced and thus a large amount of electric energy can be taken out of the thermoelectric conversion module 10 by the simple means of narrowing the flow path of the compressible fluid to be flowed in the piping.

Since other structures and features are similar to the ones of the thermoelectric conversion module 10 relating to the first embodiment, they will be omitted.

### Third Embodiment

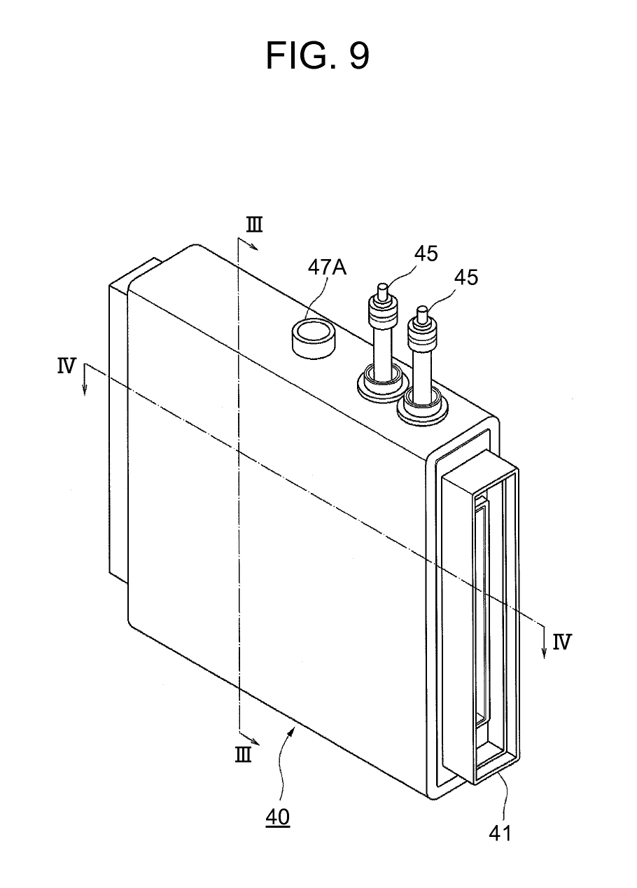

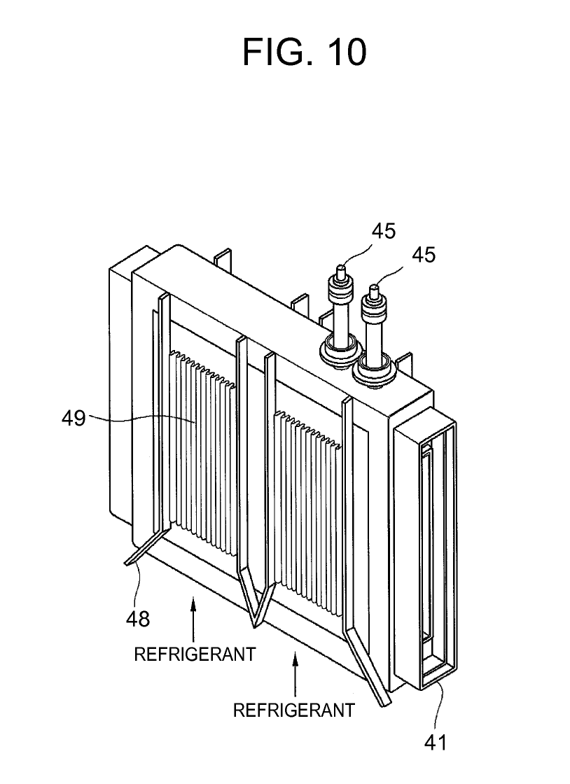

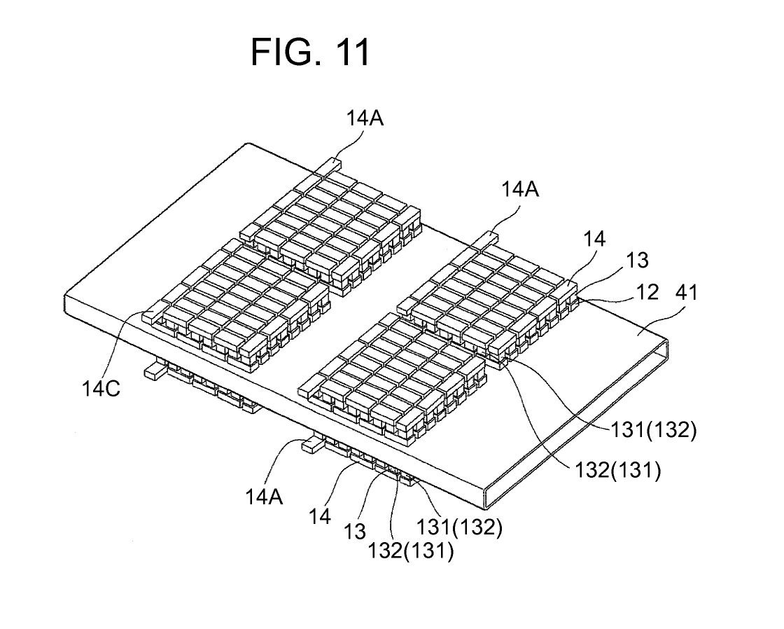

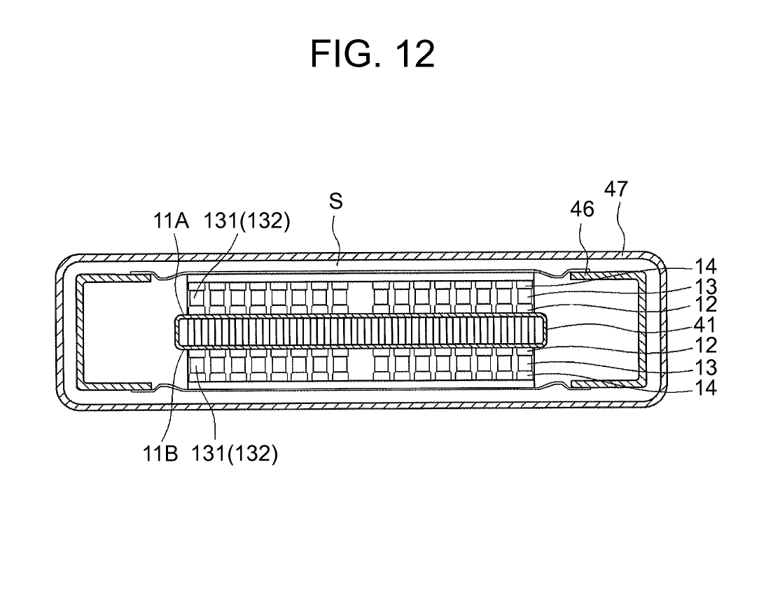

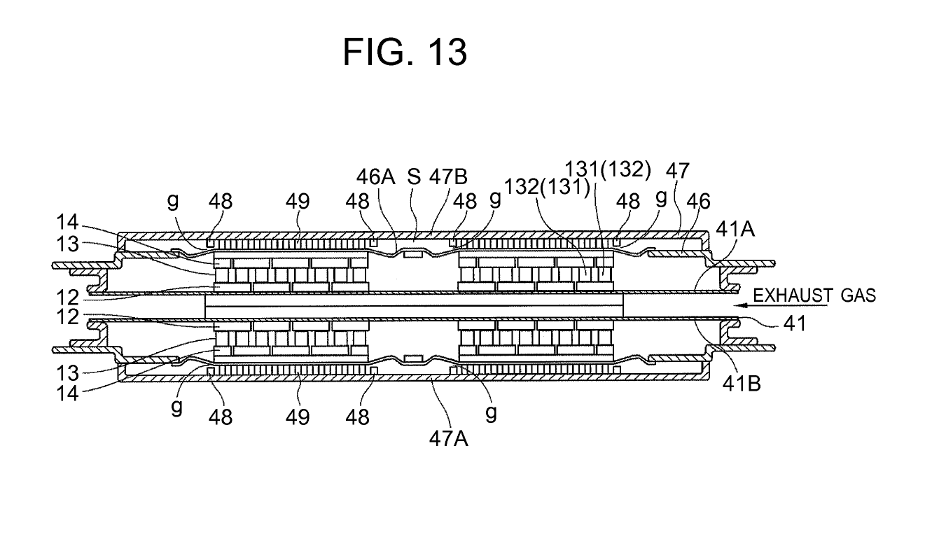

FIGS. 9 to 13 are views schematically illustrating a thermoelectric conversion module according to the present embodiment. FIG. 9 is a perspective view schematically illustrating the thermoelectric conversion module, and FIG. 10 is a perspective view schematically illustrating the state where an outer second case member is released from the thermoelectric conversion module illustrated in FIG. 9. FIG. 11 is a perspective view illustrating the state where the outer second case member and a first case member for accommodating a thermoelectric conversion element which is positioned at the inner side of the second case member are released from the thermoelectric conversion module illustrated in FIG. 9. FIG. 12 is a cross sectional view of the thermoelectric conversion module illustrated in FIG. 9, taken on line III-III, and FIG. 13 is a cross sectional view of the thermoelectric conversion module illustrated in FIG. 9, taken on line IV-IV.

Like or corresponding components in the thermoelectric conversion modules 10 and 30 illustrated in FIGS. 1 to 8 are designated by the same symbols.

As illustrated in FIGS. 9 to 13, the thermoelectric conversion module 40 includes a cylindrical piping 41 for flowing a compressible fluid which has a flat top surface 41A and bottom surface 41B and high temperature electrodes 12, 12 which are provided on the respective top surface 41A and the bottom surface 41B of the piping 41 and electrically insulated from the piping 41. Moreover, thermoelectric conversion elements 13, 13 are provided on the respective high temperature electrodes 12, 12, each thermoelectric conversion element 13 having p-type thermoelectric semiconductors 131 and n-type thermoelectric semiconductors 132 which are provided in the shape of matrix so as to be adjacent to one another and electrically connected in series with one another. Furthermore, low temperature electrodes 14, 14 are provided on the respective thermoelectric conversion elements 13, 13 so as to electrically connect the p-type thermoelectric semiconductors 131 in series with the n-type thermoelectric semiconductors 132 and to be contacted with the piping 41 in the state of electric insulation from the piping 41.

As illustrated in FIGS. 10, 12 and 13, moreover, the piping 41, the high temperature electrodes 12, 12, the thermoelectric conversion elements 13, 13 and the low temperature electrodes 14, 14 are accommodated in a first case member 46, and as illustrated in FIGS. 9, 12, and 13, the first case member 46 is accommodated in a second case member 47 so as to form a refrigerant chamber S between the first case member 46 and the second case member 47.

As illustrated in FIG. 9, an inlet 47A is formed at the second case member 47 so as to flow the refrigerant into the refrigerant chamber S. As illustrated in FIGS. 10, 12, and 13, moreover, a flow path guiding plate 48 is provided in the refrigerant chamber S to be narrowed from the introduction side of the refrigerant to the refrigerant chamber S (the side of the inlet 47A) toward the area where the thermoelectric conversion elements 13, 13 are provided. In this embodiment, the flow path guiding plate 48 is bonded with the bottom wall 47B of the second case member 47 to form a gap “g” for the top wall 46A of the first case member 46. Furthermore, a fin 49 as a heat exchange member is provided in the refrigerant chamber S, that is, in the inner area defined by the flow path guiding plate 48.

In this manner, the flow path guiding plate 47 is provided in the refrigerant chamber S formed by the first case member 46 accommodating the piping 41 for flowing the compressible fluid in the thermoelectric conversion module 40 of the present embodiment, the high temperature electrodes 12, 12 and the low temperature electrodes 14, 14 and the second case member 47 which is provided outside from the first case member 46 and accommodates the first case member 46 so as to be narrowed from the inlet 47A of the refrigerant chamber S toward the area where the thermoelectric conversion elements 13, 13 are formed. Therefore, the refrigerant flowing in refrigerant chamber S is forcibly supplied to the formation area of the thermoelectric conversion elements 13, 13 to cool the formation area more efficiently and effectively.

Therefore, since the cold heat from the refrigerant can be conducted to the side of low temperature heat source of the thermoelectric conversion elements 13, 13 effectively, in comparison to the conventional configuration where the refrigerant is flowed entirely in the refrigerant chamber S, the efficiency of utilization of the refrigerant can be enhanced. As a result, the Seebeck effect of the thermoelectric conversion element 13, 13 is enhanced to increase the efficiency of thermoelectric conversion so that a large amount of electric energy can be taken out of the thermoelectric conversion module 40.

Namely, according to this embodiment, the efficiency of thermoelectric conversion of the thermoelectric conversion elements 13, 13 can be enhanced and thus a large amount of electric energy can be taken out of the thermoelectric conversion module 40 by the simple means of providing the flow path guiding plate 48 formed so as to be narrowed from the inlet 47A of the refrigerant chamber S toward the formation area of the thermoelectric conversion elements 13, 13.

Here, the gap “g” may be formed over the flow path guiding plate 48 or in the alternative, at a portion of the flow path guiding plate 48 only if the gap “g” can exhibit the aforementioned effect/function.

In this embodiment, since the flow path guiding plate 48 is fixed to the bottom wall 47B of the second case member 47, the flow path guiding plate 48 cannot be shifted by the refrigerant flowing in the refrigerant chamber S so that the refrigerant can be stably supplied to the formation area of the thermoelectric conversion elements 13, 13 and the gap “g” can be surely formed for the first case member 46.

In this embodiment, moreover, since the fin 49 as the heat exchange member is provided in the refrigerant chamber S, the cold heat from the refrigerant flowing in the refrigerant chamber S is conducted to the side of low temperature heat source of the thermoelectric conversion elements 13, 13 effectively, thereby much increasing the efficiency of utilization of the refrigerant. As a result, the Seebeck effect of the thermoelectric conversion elements 13, 13 is much enhanced to increase the efficiency of thermoelectric conversion of the elements 13, 13 and thus a large amount of electric energy can be taken out of the thermoelectric conversion module 40.

As illustrated in FIG. 11, in the thermoelectric conversion module 40 of the present embodiment, the high temperature electrodes 12, 12, the thermoelectric conversion elements 13, 13 and the low temperature electrodes 14, 14 are formed at a plurality of areas on the top surface 41A and the bottom surface 41B of the piping 41. In this case, the thermoelectric conversion elements 13, 13 and the like provided at each of the areas are electrically connected with one another via lead wires (not shown) and the current (voltage) generated at thermoelectric conversion elements 13, 13 formed at each of the areas is taken out of the module 40 via electrode terminals 45 connected with the electrode portion 14C positioned at the leftmost-bottom end of the module 40 (refer to FIG. 9).

As described above, according to this embodiment can be provided a thermoelectric conversion module which uses as heat source waste heat from compressible fluid such as exhaust gas from various industrial equipments and automobiles and enhance thermoelectric conversion efficiency thereof and which is very practical.

### Fourth Embodiment

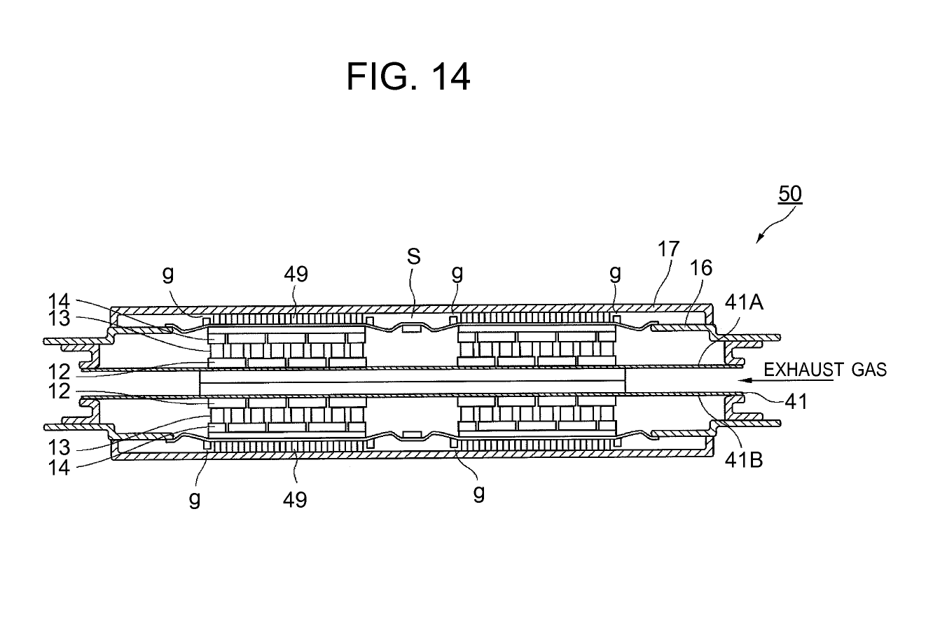

FIG. 14 is a cross sectional view schematically illustrating the thermoelectric conversion module 50 according to the present embodiment and corresponds to the cross sectional view illustrated in FIG. 13 relating to the thermoelectric conversion module 40. Like or corresponding components in the thermoelectric conversion module 40 illustrated in FIGS. 9 to 13 are designated by the same symbols.

In this embodiment, since the flow path guiding member 48 is fixed to the top wall 46A of the first case member 46, the flow path guiding plate 48 cannot be shifted by the refrigerant flowing in the refrigerant chamber S so that as described above, the refrigerant can be stably supplied to the formation area of the thermoelectric conversion elements 13, 13 and the gap “g” can be surely formed for the second case member 47.

Since other structures and features are similar to the ones of the thermoelectric conversion module 40 relating to the third embodiment, they will be omitted.

### Fifth Embodiment

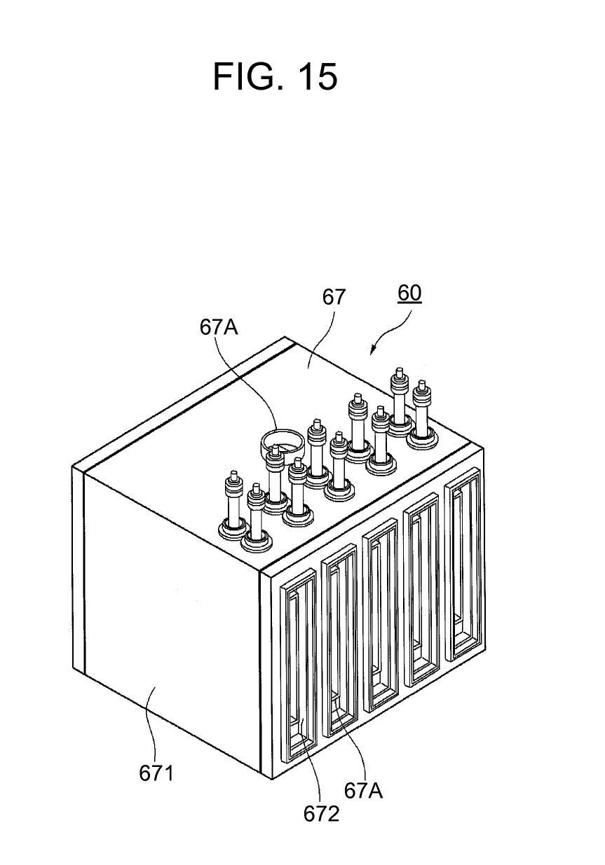

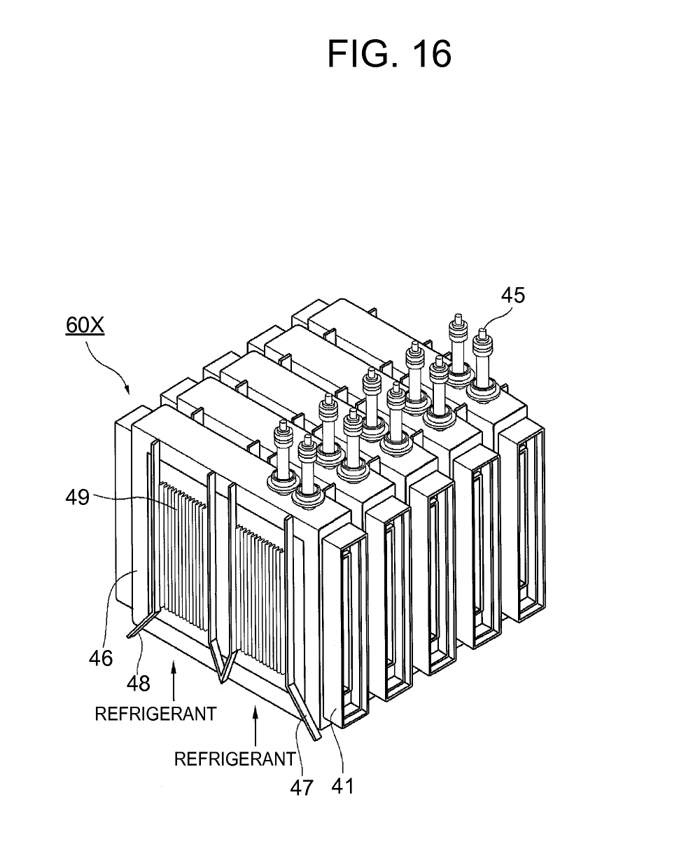

FIGS. 15 and 16 are views schematically illustrating the thermoelectric conversion module 60 according to the present embodiment. FIG. 15 is a perspective view schematically illustrating the thermoelectric conversion module 60, and FIG. 16 is a perspective view schematically illustrating the state where the outer second case member is released from the thermoelectric conversion module illustrated in FIG. 15.

Like or corresponding components in the thermoelectric conversion module 40 illustrated in FIGS. 9 to 13 are designated by the same symbols.

As illustrated in FIGS. 15 and 16, the thermoelectric conversion module 60 in this embodiment is configured such that five thermoelectric conversion module assemblies, each being designated by symbol “60X” and configured as the one illustrated in FIG. 10 where the first case member 46 is released from the thermoelectric conversion module 40 according to the third embodiment, are laminated via the respective flow path guiding plates 48 and the thus obtained laminate is accommodated in a second case member 67. Not illustrated in FIGS. 15 and 16, the flow path guiding plate 48 is provided in the refrigerant chamber formed between the first case member 46 and a second case member 67.

In the second case member 67, flanges 672 are provided at both sides of the main part 671 at which a refrigerant inlet 67A is formed and an opening 67A is formed so as to introduce the compressible fluid into the piping 41 of the assembly 60X of the thermoelectric conversion module 60.

In this embodiment, the flow path guiding plate 48 is provided in the refrigerant chamber S formed by the first case member 46 accommodating the piping 41 for flowing the compressible fluid in the assembly 60X, the high temperature electrodes 12, 12, the thermoelectric conversion elements 13, 13 containing the p-type thermoelectric semiconductors 131 and the n-type thermoelectric semiconductors 132 and the low temperature electrodes 14, 14 and the second case member 67 which is provided outside from the first case member 46 and accommodates the first case member 46 so as to be narrowed from the inlet 67A of the refrigerant chamber S toward the formation area of the thermoelectric conversion elements 13, 13. Therefore, the refrigerant flowing in refrigerant chamber S is forcibly supplied to the formation area of the thermoelectric conversion elements 13, 13 to cool the formation area more efficiently and effectively.

Therefore, since the cold heat from the refrigerant can be conducted to the side of low temperature heat source of the thermoelectric conversion elements 13, 13 effectively, in comparison to the conventional configuration where the refrigerant is flowed entirely in the refrigerant chamber S, the efficiency of utilization of the refrigerant can be enhanced. As a result, the Seebeck effect of the thermoelectric conversion element 13, 13 is enhanced to increase the efficiency of thermoelectric conversion so that a large amount of electric energy can be taken out of the thermoelectric conversion module 60.

Namely, according to the thermoelectric conversion module 60 of this embodiment, the efficiency of thermoelectric conversion of the thermoelectric conversion elements 13, 13 can be enhanced and thus a large amount of electric energy can be taken out of the thermoelectric conversion module 60 by the simple means of providing the flow path guiding plate 48 formed so as to be narrowed from the inlet 67A of the refrigerant chamber S toward the formation area of the thermoelectric conversion elements 13, 13.

In this embodiment, since the laminated structure as illustrated in FIG. 15 is employed, the assemblies of the thermoelectric conversion module 60 is substantially connected in parallel with one another. In this manner, a much large of electric energy can be taken out of the thermoelectric conversion module 60 of the present invention, in comparison with the thermoelectric conversion module 40 according to the third embodiment.

Since other structures and features are similar to the ones of the thermoelectric conversion module 40 relating to the third embodiment, they will be omitted.

Although the present invention was described in detail with reference to the above examples, this invention is not limited to the above disclosure and every kind of variation and modification may be made without departing from the scope of the present invention.

Explanation of the Symbols
10, 20, 40, 50, 60 thermoelectric conversion module
21, 31, 41 piping
21D, 31D fin (in piping)
12 high temperature electrode
13 thermoelectric conversion element
14 low temperature electrode
15 case member
16 space (between low temperature electrode and case member)
17 electrode terminal
18 inlet of refrigerant
19 outlet of refrigerant
21S, 31S inner space corresponding to non-formation area of thermoelectric conversion element in piping
23 sealing member
31F dent processing
45 electrode terminal
46 first case member
47 second case member
48 flow path guiding plate
49 fin

1. A thermoelectric conversion module, comprising:
a piping for flowing a compressible fluid;
high temperature electrodes which are provided on a top surface and a bottom surface of the piping and electrically insulated from the piping;
thermoelectric conversion elements which are provided on the respective high temperature electrodes, each element containing at least a pair of p-type thermoelectric semiconductor and n-type thermoelectric semiconductor which are electrically connected in series with one another;
low temperature electrodes which are provided on the respective thermoelectric conversion elements and electrically connect the p-type thermoelectric semiconductor in series with the n-type thermoelectric semiconductor; and
a first case member for accommodating the piping, the high temperature electrodes, the thermoelectric conversion elements and the low temperature electrodes so as to form a space for flowing a refrigerant for the low temperature electrodes,
wherein the compressible fluid or the refrigerant is flowed to areas where the thermoelectric conversion elements are provided at an inner side or an outer side of the piping.

2. The thermoelectric conversion module as set forth in claim 1,
wherein at least a portion of an inner space, which is orthogonal to a direction of flow of the compressible fluid, the inner space corresponding to a non-formation area of the thermoelectric conversion elements, is closed

3. The thermoelectric conversion module as set forth in claim 2,
wherein the at least a portion of the inner space is closed by providing a sealing member in the inner space.

4. The thermoelectric conversion module as set for in claim 2,
wherein the at least a portion of the inner space is closed by denting at least a side surface of the piping toward the inner space.

5. The thermoelectric conversion module as set forth in claim 1, further comprising:
a second case member which is provided outside of the first case member so as to form a refrigerant chamber for flowing the refrigerant for the low temperature electrodes and to accommodate the first case member; and
a flow path guiding plate which is provided in the refrigerant chamber so as to be narrowed from an inlet of the refrigerant chamber toward a formation area of the thermoelectric conversion element.

6. The thermoelectric conversion module as set forth in claim 5,
wherein the flow path guiding plate is provided so as to form a gap against at least a portion of a top wall of the first case member or at least a portion of a bottom wall of the second case member.

7. The thermoelectric conversion module as set forth in claim 6,
wherein the flow path guiding plate is provided so as to be bonded with the at least a portion of a top wall of the first case member or the at least a portion of a bottom wall of the second case member.

8. The thermoelectric conversion module as set forth in claim 5,
wherein a heat exchange member is provided in the refrigerant chamber.

9. The thermoelectric conversion module as set forth in claim 6,
wherein a heat exchange member is provided in the refrigerant chamber.

10. The thermoelectric conversion module as set forth in claim 7,
wherein a heat exchange member is provided in the refrigerant chamber.
